(19) United States
(12) Patent Application Publication
(10) Pub. No.: US 2006/0158542 A1
(43) Pub. Date: Jul. 20, 2006

(54) Photosensitive part and solid-state image pickup device

(75) Inventors: Seiichiro Mizuno, Hamamatsu-shi (JP); Haruhiro Funakoshi, Hamamatsu-shi (JP); Tetsuya Taka, Hamamatsu-shi (JP)

Correspondence Address: DRINKER BIDDLE & REATH (DC), 1500 K STREET, N.W., SUITE 1100, WASHINGTON, DC, 20005-1209, US

(73) Assignee: HAMAMATSU PHOTONICS K.K.

(21) Appl. No.: 11/291,999

(22) Filed: Dec. 2, 2005

Related U.S. Application Data
(63) Continuation-in-part of application No. PCT/JP05/06301, filed on Mar. 31, 2005.

(30) Foreign Application Priority Data
Apr. 1, 2004 (JP) P2004-109301

(51) Int. Cl. H04N 5/335

(52) U.S. Cl. 348/308

(57) ABSTRACT

A transmission transistor T₂ transfers charges generated in a photodiode PD to a first capacitor part C₁₁ via a first switch SW₁₁, and transfers the charges to a second capacitor part C₁₂ via a second switch SW₁₂. An amplification transistor T₁ outputs a voltage corresponding to the amount of accumulated charges in at least one of a first capacitor part C₁₁ and a second capacitor part C_{12,} connected to a gate terminal, and a gate terminal of the amplification transistor T₁ is connected to at least one of the first capacitor part C₁₁ and the second capacitor part C₁₂.

### CROSS-REFERENCE TO RELATED APPLICATIONS

This is a continuation-in-part application of application serial no. PCT/JP2005/006301 filed on Mar. 31, 2005, now pending and including US as designation states, and incorporated by reference in its entirety.

### FIELD OF THE INVENTION

This invention relates to a photosensitive part and a solid-state image pickup device.

### RELATED BACKGROUND ART

A solid-state image pickup device is provided with a light detecting part in which a plurality of photosensitive parts are one-dimensionally or two-dimensionally arranged. The solid-state image pickup device can output an electric signal value denoting the incident intensity to the photosensitive part in each pixel position from the photosensitive part, and pick up an image based on the electric signal value. In such a solid-state image pickup device, when the difference in the amount of incident light between pixel positions is large (that is, when the contrast of the image which should be picked up is high), it is required that the image having excellent contrast is obtained by picking up.

However, a photo sensor circuit disclosed in Patent Document 1 includes a photodiode as the photosensitive part, accumulates the charges generated by the optical incidence to the photodiode in the capacity part in the integration circuit, and outputs the voltage corresponding to the amount of accumulated charges from the integration circuit. In this solid-state image pickup device, the capacity value of the capacity part in the integration circuit is variable, and thereby the expansion of the dynamic range of optical detection is attained. It is considered that the solid-state image pickup device capable of obtaining an image having excellent contrast by picking up can be realized by using a technique disclosed in Japanese Patent No. 3146502 (referred as Patent Document hereinbelow) in the solid-state image pickup device.

In the technique disclosed in Patent Document 1, an optical detection having high sensitivity when the amount of incident light is small can be performed by reducing the capacity value of the capacity part of the integration circuit. Therefore, the signal charges outputted from the photodiode are amplified by the integration circuit and a noise is also amplified by the integration circuit. Thereby, the S/N ratio of the optical detection is poor. Even if the solid-state image pickup device using the technique disclosed in Patent Document 1 can obtain the image having excellent contrast, the S/N ratio of the image is poor.

### SUMMARY OF THE INVENTION

The present invention has been developed to eliminate the problem described above, and it is an object of the present invention to provide a solid-state image pickup device capable of obtaining the image having excellent contrast and S/N ratio, and a photosensitive part suitably used in the solid-state image pickup device.

A photosensitive part according to the present invention comprising:

(1) a photodiode for generating charges corresponding to the intensity of incident light;

(2) a first capacitor part and a second capacitor part for respectively accumulating the charges;

(3) an amplification transistor having a gate terminal connected to at least one of the first capacitor part and the second capacitor part and outputting a voltage corresponding to the charges accumulated in at least one of the first capacitor part and the second capacitor part, connected to the gate terminal;

(4) a transmission transistor for transferring the charges generated in the photodiode to the first capacitor part via a first switch and transferring the charges to the second capacitor part via a second switch;

(5) a discharge transistor for initializing the charges of each of the first capacitor part and the second capacitor part; and

(6) a selection transistor for alternatively outputting the voltage outputted from the amplification transistor.

This photosensitive part is provided with the first capacitor part and second capacitor part for respectively accumulating the charges, and the charges of the first capacitor part and second capacitor part are initialized by the discharge transistor. The charges generated in the photodiode according to the light incidence is transferred to the first capacitor part via the first switch through the transmission transistor, and is transferred to the second capacitor part via the second switch. The gate terminal of the amplification transistor is connected to at least one of the first capacitor part and the second capacitor part, and the voltage corresponding to the charges accumulated in at least one of the first capacitor part and the second capacitor part, connected to the gate terminal is outputted through the amplification transistor and the selection transistor.

A solid-state image pickup device of the present invention comprising:

(1) a light detecting part including sections A_{1,1} to A_{M,N} of M×N pieces one-dimensionally or two-dimensionally arranged and having the photosensitive parts of K pieces according to the present invention arranged in a section A_{m,n} in the m-th line and n-th column;

(2) a holding part for holding first voltages outputted through the selection transistor from the amplification transistor when the gate terminal of the amplification transistor of each of the photosensitive part of K pieces contained in the section A_{m,n} is connected to at least one of the first capacitor part and the second capacitor part, and holding second voltages outputted through the selection transistor from the amplification transistor when the gate terminal of the amplification transistor is connected to both the first capacitor part and the second capacitor part; and

(3) a calculating part for calculating and outputting the added value of the first voltages outputted from each of the photosensitive parts of K pieces contained in the section A_{m,n} and held by the holding part, and calculating and outputting the average value of the second voltages outputted from each of the photosensitive part of K pieces contained in the section A_{m,n} and held by the holding part, wherein M and N are an integer of 1 or more; at least one of M and N is an integer of 2 or more; K is an integer of 2 or more; m is an optional integer of 1 to M; and n is an optional integer of 1 to N. Herein, it is preferable that the solid-state image pickup device further comprises a selecting part for inputting the added value and average value outputted from the calculating part for each section A_{m,n}, outputting the added value when the absolute value of the added value is smaller than a predetermined value and outputting the average value when not so.

In the light detecting part of the solid-state image pickup device, the sections A_{1,1} to A_{M,N} of M×N pieces are one-dimensionally or two-dimensionally arranged, and the photosensitive parts of K pieces according to the present invention are arranged in the section A_{m,n} in the m-th line and n-th column. The first voltage outputted through the selection transistor from the amplification transistor when the gate terminal of the amplification transistor of each of the photosensitive part of K pieces contained in the section A_{m,n} is connected to at least one of the first capacitor part and the second capacitor part, and the second voltage outputted through the selection transistor from the amplification transistor when the gate terminal of the amplification transistor is connected to both the first capacitor part and the second capacitor part are held by the holding part.

The calculating part calculates and outputs the added value of the first voltage outputted from each of the photosensitive parts of K pieces contained in the section A_{m,n} and held by the holding part, and calculates and outputs the average value of the second voltage outputted from each of the photosensitive part of K pieces contained in the section A_{m,n} and held by the holding part. When the selecting part is further provided, the selecting part inputs the added value and average value outputted from the calculating part for each section A_{m,n}, selects and outputs the added value when the absolute value of the added value is smaller than the predetermined value, and selects and outputs the average value when not so.

It is preferable that the solid-state image pickup device according to the present invention, further comprises:

(1) a connection switching part having a first end provided for each of the photosensitive parts of K pieces contained in the section A_{m,n} and connected to the discharge transistor of the photosensitive part, and a second end for inputting bias potential for initializing the charges of each of the first capacitor part and second capacitor part of the photosensitive part, and a third end, and electrically connecting between the first end and the second end, or between the first end and the third end; and (2) an integration circuit having an input terminal connected to the third end of the connection switching part, accumulating the charges flowing-in through the first end and the third end of the connection switching part from the photosensitive parts of K pieces contained in the section A_{m,n} in a capacitor, and outputting the integration value corresponding to the amount of accumulated charges.

It is preferable that the solid-state image pickup device further comprises a selecting part for inputting the added value and average value outputted from the calculating part for each section A_{m,n}, inputting the integration value outputted from the integration circuit, outputting the added value when the absolute value of the added value is smaller than a first predetermined value, outputting the average value when the absolute value of the added value is larger than the first predetermined value and the absolute value of the average value is smaller than a second predetermined value, and outputting the integration value in neither case.

In this case, the charges generated in the photodiode of each of the photosensitive parts of K pieces contained in a certain section A_{m,n} are inputted into the integration circuit through the connection switching part, and are accumulated in the capacitor of the integration circuit. The integration value corresponding to the amount of accumulated charges is outputted from the integration circuit. When the selecting part is further provided, any of the added value and average value outputted from the calculating part, and the integration value outputted from the integration circuit is selected for each section A_{m,n} by the selecting part and is outputted.

The present invention will be more fully understood from the detailed description given hereinbelow and the accompanying drawings, which are given by way of illustration only and are not to be considered as limiting the embodiment.

Further scope of applicability of the embodiment will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1 is a schematic block diagram of a solid-state image pickup device 1 according to the embodiment.

FIG. 2 is a block diagram of a section A_{m,n} min a light detecting part 10 and holding circuit Hₙ in a holding part 20 of the solid-state image pickup device 1 according to the embodiment.

FIG. 3 is a circuit diagram of a photosensitive part a_{i,j} of the section A_{m,n} in the light detecting part 10 and partial holding circuit h_{i,j} of the holding circuit Hₙ in the holding part 20 of the solid-state image pickup device 1 according to the embodiment.

FIG. 4 is a sectional view of a photodiode PD.

FIG. 5 is an explanatory view of a calculating part 30 of the solid-state image pickup device 1 according to the embodiment.

FIG. 6 is a circuit diagram of an integration circuit 40 and CDS circuit 50 of the solid-state image pickup device 1 according to the embodiment.

FIG. 7 is a timing chart for explaining the operation of the solid-state image pickup device 1 according to the embodiment.

FIG. 8 is a timing chart for explaining the operation of the solid-state image pickup device 1 according to the embodiment.

### DETAILED DESCRIPTION OF THE PREFERRED EMBODIMENTS

Hereinafter, the embodiments of the present invention will be described in detail with reference to the accompanying drawings. In the description of the drawings, identical components are designated by the same reference numerals, and overlapping description is omitted.

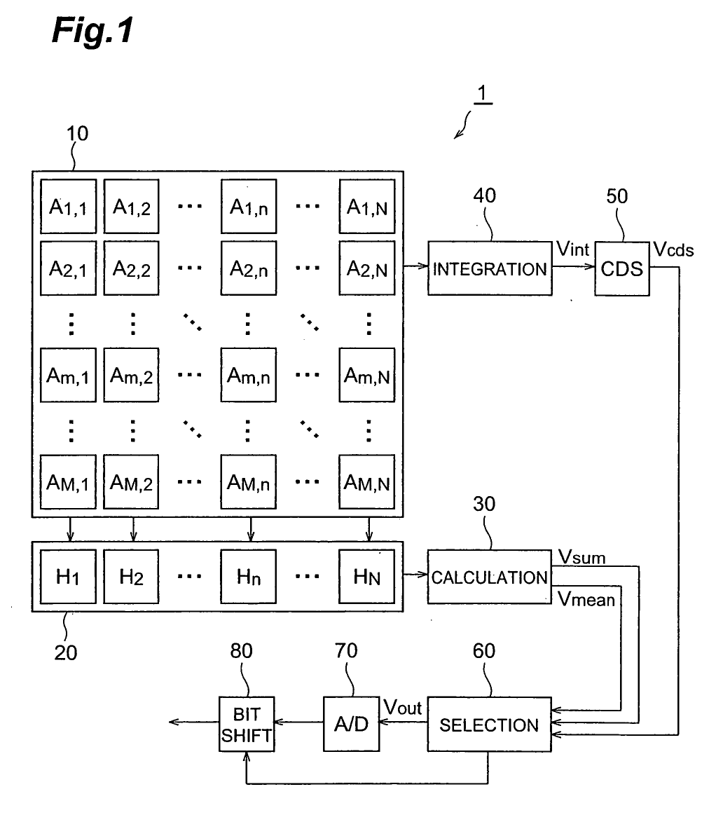

FIG. 1 is a schematic block diagram of a solid-state image pickup device 1 according to the embodiment.

The solid-state image pickup device 1 shown in the figure is provided with a light detecting part 10, a holding part 20, a calculating part 30, an integration circuit 40, a CDS circuit 50, a selecting part 60, an A/D converter circuit 70 and a bit shift circuit 80. Although lines are shown between components in the figure, the number of lines is not necessarily in agreement with the actual number of lines.

The light detecting part 10 contains sections A_{1,1} to A_{M,N} of M×N pieces one-dimensionally or two-dimensionally arranged and having a common constitution in a substantially rectangular region as a whole. The section A_{m,n} is located in the m-th line and n-th column. As described below, photosensitive parts of K pieces are arranged in each section A_{m,n}. M and N are an integer of 1 or more; at least one of M and N is an integer of 2 or more; K is an integer of 2 or more; m is an optional integer of 1 to M; and n is an optional integer of 1 to N.

The holding part 20 contains holding circuits H₁ to H_{N} of N pieces having a common constitution. Each holding circuit Hₙ is provided so as to correspond to the sections A_{l,n} to A_{M,n} of M pieces in the n-th column in the light detecting part 10. The voltage held and outputted by each of the holding circuits H₁ to H_{N} of N pieces in the holding part 20 is inputted into the calculating part 30, and the calculating part 30 performs a required operation based on the input voltage, and outputs a voltage denoting the operation result.

Only one integration circuit 40 is provided for the section A_{1,1} to A_{M,N} of M×N pieces in the light detecting part 10. This integration circuit 40 accumulates the charges outputted from the photosensitive parts of K pieces contained in each section A_{m,n} in the light detecting part 10 in a capacitor, and outputs the voltage corresponding to the amount of accumulated charges. The voltage outputted from the integration circuit is inputted into the CDS (Correlated Double Sampling) circuit 50, and the CDS circuit 50 outputs the voltage corresponding to the difference in input voltages in a certain time and another time.

The voltages outputted from the calculating part 30 and the CDS circuit 50 are inputted into the selecting part 60, and the selecting part 60 selects and outputs any one voltage thereof. The voltage (analog value) outputted from the selecting part 60 is inputted into the A/D converter circuit 70, and the AID converter circuit 70 converts this voltage into a digital value, and outputs this digital value. The digital value outputted from the A/D converter circuit 70 is inputted into the bit shift circuit 80, and the bit shift circuit 80 shifts and outputs the digital value by only the required number of bits in accordance with any selected in the selecting part 60.

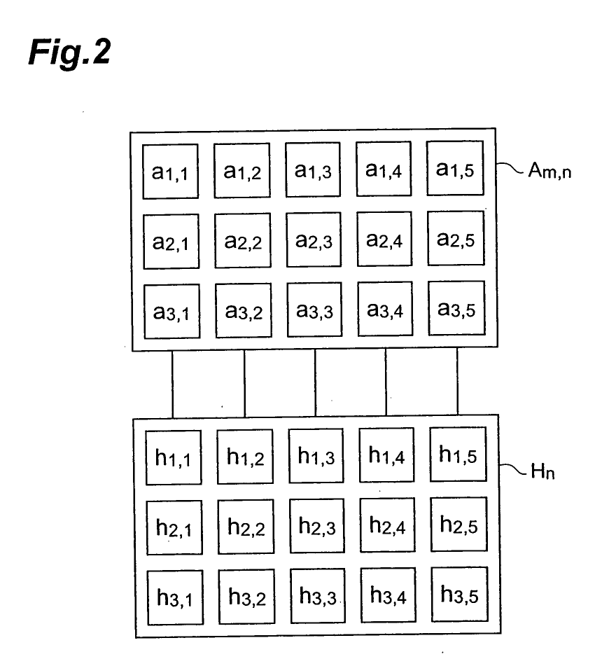

FIG. 2 is a block diagram of the section A_{m,n} in the light detecting part 10 and holding circuit Hₙ in the holding part 20 of the solid-state image pickup device 1 according to the embodiment. The photosensitive parts (K=15 in this embodiment) a_{1,1} to a_{3,5} of K pieces having a shared constitution are arranged in each section A_{m,n}. Each holding circuit Hₙ includes partial holding circuits h_{1,1} to h_{3,5} of 15 pieces having a common constitution. The partial holding circuit h_{i,j} in each holding circuit Hₙ is provided so as to correspond to the photosensitive part a_{i,j} of each of the sections A_{l,n} to A_{M,n} of M pieces in the n-th column in the light detecting part 10. However, i is an optional integer of 1 to 3, and j is an optional integer of 1 to 5.

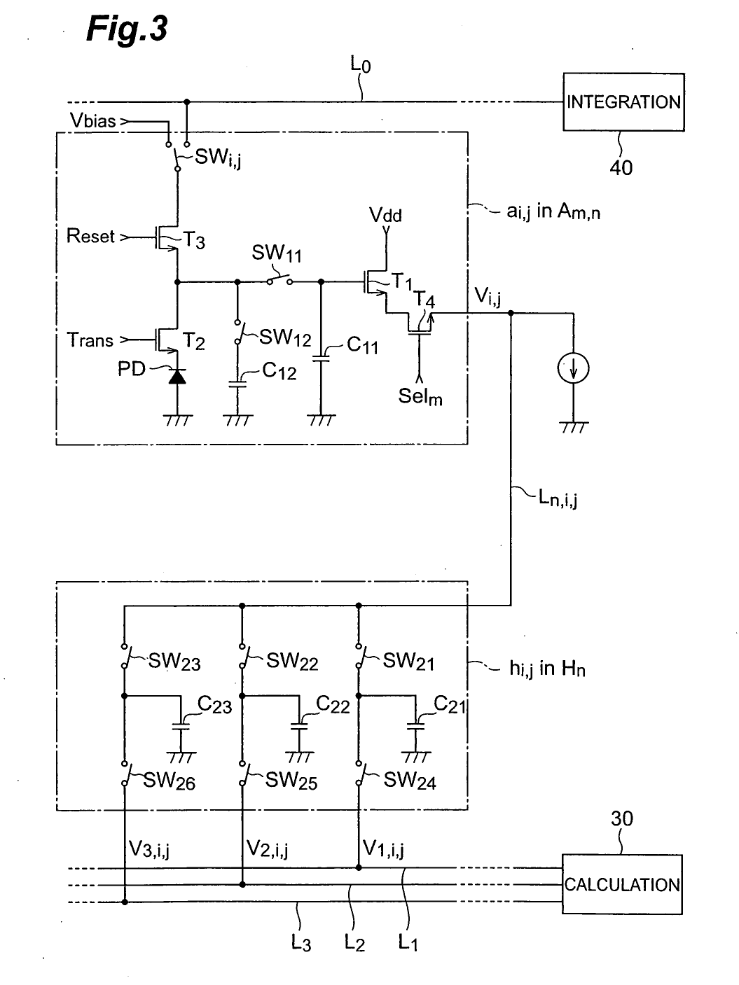

FIG. 3 is a circuit diagram of the photosensitive part a_{i,j} of the section A_{m,n} in the light detecting part 10 and partial holding circuit h_{i,j} of the holding circuit Hₙ in the holding part 20 of the solid-state image pickup device 1 according to the embodiment. Each photosensitive part a_{i,j} is provided with the photodiode PD for generating charges corresponding to the intensity of incident light, a first capacitor part C₁₁ and second capacitor part C₁₂, respectively, accumulating the charges, an amplification transistor T₁ in which a gate terminal is connected to at least one of the first capacitor part C₁₁ and the second capacitor part C₁₂, a transmission transistor T₂ for transferring the charges generated in the photodiode PD to the first capacitor part C₁₁ or the second capacitor part C₁₂, a discharge transistor T₃ for respectively initializing the charges of the first capacitor part C₁₁ and second capacitor part C₁₂, and a selection transistor T₄ for alternatively outputting the voltage outputted from the amplification transistor T₁.

The gate terminal of the amplification transistor T₁ is directly connects to the first capacitor part C₁₁, and the gate terminal is connected to the second capacitor part C₁₂ via the first switch SW₁₁ and the second switch SW₁₂. A drain terminal of the amplification transistor T₁ is set to a bias potential V_{dd}. A source terminal of the amplification transistor T₁ is connected to a drain terminal of the selection transistor T₄. A source terminal of the selection transistor T₄ is connected to a line L_{n,i,j}. The other end of each of the first capacitor part C₁₁ and second capacitor part C₁₂ is grounded. The first capacitor part C₁₁ and the second capacitor part C₁₂ may be respectively a parasitic capacitance, or may be a capacity part made intentionally.

A drain terminal of the transmission transistor T₂ is connected to a source terminal of the discharge transistor T₃, and is connected to the gate terminal of the first capacitor part C₁₁ and the amplification transistor T₁ via the first switch SW₁₁. The drain terminal is connected to the second capacitor part C₁₂ via the second switch SW₁₂. A source terminal of the transmission transistor T₂ is connected to a cathode terminal of the photodiode PD. An anode terminal of the photodiode PD is grounded. A drain terminal of the discharge transistor T₃ is connected to a switch SW_{i,j}.

A transmission control signal Trans into the gate terminal is inputted into the transmission transistor T₂, and the transmission transistor T₂ transfers the charges generated in the photodiode PD to the capacity part C₁₁ or C₁₂ when the transmission control signal Trans is at a high level and the switch SW₁₁ or SW₁₂ is closed. A discharge control signal Reset is inputted into the gate terminal of the discharge transistor T₃, and the discharge transistor T₃ reduces the resistance between the switch SW_{i,j} and the source terminal of the discharge transistor T₃ when the discharge control signal Reset is at a high level. A m-th line select control signal Selₘ is inputted into the gate terminal of the selection transistor T₄, and the selection transistor T₄ outputs the voltage outputted from the amplification transistor T₁ to the line L_{n,i,j} when the m-th line select control signal Selₘ is at a high level.

Each line L_{n,i,j} is connected to the selection transistor T₄ of the photosensitive part a_{i,j} of each of the sections A_{l,n} to A_{M,n} of M pieces in the n-th column in the light detecting part 10. A constant current source is connected to each line L_{n,i,j,}, and the amplification transistor T₁ and the selection transistor T₄ of each photosensitive part a_{i,j} constitute a source follower circuit.

The switch SW_{i,j} acts as the connection switching part provided for each photosensitive part a_{i,j}. The switch SW_{i,j} has a first end connected to the discharge transistor T₃ of the photosensitive part a_{i,j}, a second end for inputting a bias potential V_{bias} for initializing the charges of each of the first capacitor part C₁₁ and second capacitor part C₁₂ of the photosensitive part a_{i,j}, and a third end connected to the input end of the integration circuit 40 via a line L₀. The first end is electrically connected to the second end, or the first end is electrically connected to the third end.

This switch SW_{i,j} inputs bias potential V_{bias} into the discharge transistor T₃ when the first end is electrically connected to the second end. When the first end is electrically connected to the third end, and the discharge control signal Reset and transmission control signal Trans are respectively at a high level, the switch SW_{i,j} inputs the charges generated in the photodiode PD in the photosensitive part a_{i,j} into the integration circuit 40.

As shown in FIG. 3, each partial holding circuit h_{i,j} is provided with switches SW₂₁ to SW₂₆ and the capacitors C₂₁ to C₂₃. Each partial holding circuit h_{i,j} can hold three voltages corresponding to the capacitors C₂₁ to C₂₃.

The one end of the switch SW₂₁ is connected to the one end of the switch SW₂₄. The other end of the switch SW₂₁ is connected to the line L_{n,i,j}, and the other end of the switch SW₂₄ is connected to the line L₁. The capacitor C₂₁ is provided between the connecting point of the switch SW₂, and switch SW₂₄, and the grounding potential. If the switch SW₂₁ changes to an open state from a closed state when the switch SW₂₄ is opened, the voltage V_{i,j} inputted through the line L_{n,i,j} just before the switch SW₂₁ changes to the open state is held in the capacitor C₂₁. When the switch SW₂₁ is opened and the switch SW₂₄ is closed, the voltage V_{1,i,j} held in the capacitor C₂₁ is outputted to the line L₁.

The one end of the switch SW₂₂ is mutually connected to the one end of the switch SW₂₅. The other end of the switch SW₂₂ is connected to the line L_{n,i,j}, and the other end of the switch SW₂₅ is connected to the line L₂. The capacitor C₂₂ is provided between the connecting point of the switch SW₂₂ and switch SW₂₅, and the grounding potential. If the switch SW₂₂ changes to the open state from the closed state when the switch SW₂₅ is opened, the voltage V_{i,j} inputted through the line L_{n,i,j} just before the switch SW₂₂ changes to the open state is held in the capacitor C₂₂. When the switch SW₂₂ is opened and the switch SW₂₅ is closed, the voltage V_{2,i,j} held in the capacitor C₂₂ is outputted to the line L₂.

The one end of the switch SW₂₃ is connected to the one end of the switch SW₂₆. The other end of the switch SW₂₃ is connected to the line L_{n,i,j}, and the other end of the switch SW₂₆ is connected to the line L₃. The capacitor C₂₃ is provided between the connecting point of the switch SW₂₃ and switch SW₂₆, and grounding potential. When the switch SW₂₃ changes to the open state from the closed state when the switch SW₂₆ is opened, the voltage V_{i,j} inputted through the line L_{n,i,j} just before the switch SW₂₃ changes to the open state is held in the capacitor C₂₃. When the switch SW₂₃ is opened and the switch SW₂₆ is closed, the voltage V_{3,i,j} held in the capacitor C₂₃ is outputted to the line L₃.

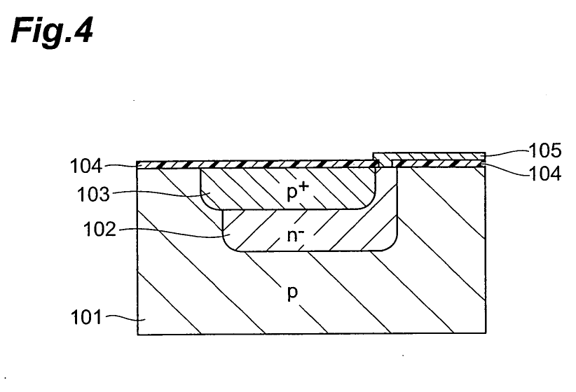

FIG. 4 is a sectional view of the photodiode PD (refer to FIG. 3). It is preferable that each photodiode PD is a buried type as shown in this figure. That is, these photodiodes have an n⁻-type second semiconductor region 102 formed on a p-type first semiconductor region 101, and a p⁺-type third semiconductor region 103 formed on the second semiconductor region 102. The first semiconductor region 101 and the second semiconductor region 102 form a pn junction, and the second semiconductor region 102 and the third semiconductor region 103 form a pn junction. An insulating layer 104 is formed on these semiconductor regions, and the second semiconductor region 102 is electrically connected to a metal layer 105. Thus, when the photodiode is a buried type, the photodiode suppresses the generation of leak current, and has an excellent S/N ratio of optical detection.

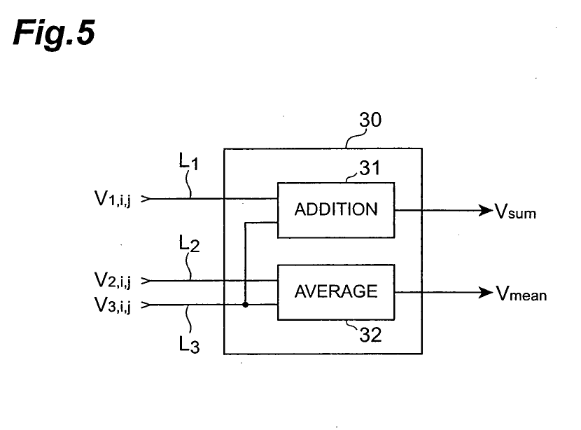

FIG. 5 is an explanatory view of a calculating part 30 of the solid-state image pickup device 1 according to the embodiment. The calculating part 30 is connected to each of the partial holding circuits h_{i,j} (refer to FIG. 3) of 15 pieces in the holding part circuit Hₙ through the lines L₁ to L₃, and has an adding part 31 and an average part 32.

The adding part 31 calculates the added value of the voltage V_{1,i,j} outputted from the photosensitive parts a_{i,j} (refer to FIG. 2) of 15 pieces in the section A_{m,n} for each of the sections A_{m,n} (refer to FIG. 1) of M×N pieces in the light detecting part 10, and held in the capacitor C₂₁ of each of the partial holding circuits h_{i,j} of 15 pieces in the holding circuit Hₙ, and outputs this added value Vₛᵤₘ. At this time, the added value of the voltage V_{3,i,j} held in the capacitor C₂₃ is reduced from the added value of the voltage V_{1,i,j} held in the capacitor C₂₁. That is, the added value Vₛᵤₘ is calculated for each of the sections A_{m,n} of M×N pieces in the light detecting part 10, and is represented by the following formula (1).

$$\begin{matrix}[ Formula 1 ] & \\ {V}_{sum} = {\sum }_{i , j} ( {V}_{1 , i , j} - {V}_{3 , i , j} ) & ( 1 )\end{matrix}$$

The average part 32 calculates the average value of the voltages V_{2,i,j} outputted from the photosensitive parts a_{i,j} of 15 pieces (refer to FIG. 2) in the section A_{m,n} for each of the sections A_{m,n} of M×N pieces in the light detecting part 10 (refer to FIG. 1) and held in the capacitor C₂₂ of each of the partial holding circuits h_{i,j} of 15 pieces in the holding circuit Hₙ, and outputs this average value Vₘₑₐₙ. At this time, the average value of the voltages V_{3,i,j} held in the capacitor C₂₃ is reduced from the average value of the voltages V_{2,i,j} held in the capacitor C₂₂. That is, the average value Vₘₑₐₙ is calculated for each of the sections A of M×N pieces in the light detecting part 10, and is represented by the following formula (2).

$$\begin{matrix}[ Formula 2 ] & \\ {V}_{mean} = \frac{1}{15} {\sum }_{i , j} ( {V}_{2 , i , j} - {V}_{3 , i , j} ) & ( 2 )\end{matrix}$$

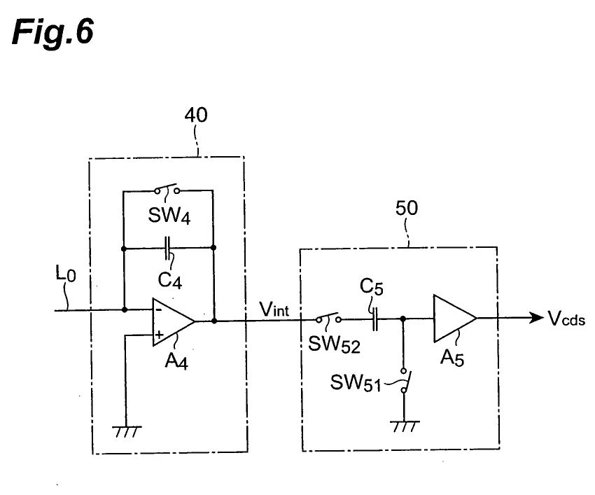

FIG. 6 is a circuit diagram of the integration circuit 40 and CDS circuit 50 of the solid-state image pickup device 1 according to the embodiment.

The integration circuit 40 is provided with an amplifier A₄, a capacitor C₄ and a switch SW₄. A non-inverted input terminal of the amplifier A₄ is grounded. The inverted input terminal of the amplifier A₄ is connected to the line L₀. The capacitor C₄ and the switch SW₄ are mutually connected in parallel, and are provided between the inverted input terminal and output terminal of the amplifier A₄. The capacitor C₄ is discharged by closing the switch SW₄ in this integration circuit 40, and the output voltage is initialized. When the switch SW₄ is opened, the charges flowing-in through the line L₀ are accumulated in the capacitor C₄, and the voltage Vᵢₙₜ corresponding to the amount of accumulated charges in this capacitor C₄ is outputted.

The CDS circuit 50 has switches SW₅₁ and SW₅₂, a capacitor C₅ and an amplifier A₅. The one end of the capacitor C₅ is grounded via the switch SW₅₁, and is connected to the input terminal of the amplifier A₅. The other end of the capacitor C₅ is connected to the output terminal of the amplifier A₄ of the integration circuit 40 via the switch SW₅₂. In this CDS circuit 50, the switch SW₅₁ changes to the open state from the closed state at a first time, and the switch SW₅₂ changes to the open state from the closed state at a second time, and thereby the voltage V_{cds} corresponding to the difference of the voltages Vᵢₙₜ outputted from the integration circuit 40 is outputted in each of the first time and second time.

The added value Vₛᵤₘ and average value Vₘₑₐₙ outputted from the calculating part 30 are inputted into the selecting part 60 (refer to FIG. 1), and the voltage V_{cds} (becoming nearly equal to the integration value Vᵢₙₜ outputted from the integration circuit 40) outputted from the CDS circuit 50 is inputted. When the absolute value of the added value Vₛᵤₘ is smaller than a first predetermined value Vₜₕ₁, the selecting part 60 outputs the added value Vₛᵤₘ. When the absolute value of the added value Vₛᵤₘ is larger than the first predetermined value Vₜₕ₁ and the absolute value of the average value Vₘₑₐₙ is smaller than the second predetermined value Vₜₕ₂, the selecting part 60 outputs the average value Vₘₑₐₙ.

In neither case, the selecting part 60 outputs the integration value Vᵢₙₜ (that is, voltage V_{cds}). That is, the voltage Vₒᵤₜ outputted from the selecting part 60 is represented by the following formula (3). A select signal denoting whether any of the added value Vₛᵤₘ, average value Vₘₑₐₙ and voltage V_{cds} is selected and is outputted as the voltage Vₒᵤₜ is outputted from the selecting part 60.

$$\begin{matrix}[ Formula 3 ] & \\ {V}_{out} = \{ \begin{matrix}{V}_{sum} ( \vert {V}_{sum} \vert < {V}_{th1} ) \\ {V}_{mean} ( {V}_{th1} \leq \vert {V}_{sum} \vert , \vert {V}_{mean} \vert < {V}_{th2} ) \\ {V}_{cdx} ( {V}_{th2} \leq \vert {V}_{mean} \vert )\end{matrix} & ( 3 )\end{matrix}$$

The voltage Vₒᵤₜ outputted from the selecting part 60 is inputted into the A/D converter circuit 70 (refer to FIG. 1), and the A/D converter circuit 70 changes the voltage Vₒᵤₜ into the digital value, and outputs the digital value. The digital value outputted from the A/D converter circuit 70 is inputted into the bit shift circuit 80, and the bit shift circuit 80 shifts the digital value by only the required number of bits corresponding to any selected in the selecting part 60, and outputs the shifted digital value.

That is, when the voltage Vₒᵤₜ outputted from the selecting part 60 is the added value Vₛᵤₘ, the bit shift circuit 80 does not shift the bits of the digital value outputted from the A/D converter circuit 70. When the voltage Vₒᵤₜ outputted from the selecting part 60 is the average value Vₘₑₐₙ, the bit shift circuit 80 shifts the digital value outputted from the A/D converter circuit 70 by only p bits to a higher order. When the voltage Vₒᵤₜ outputted from the selecting part 60 is the voltage V_{cds}, the bit shift circuit 80 shifts the digital value outputted from the A/D converter circuit 70 by only q bits to a higher order (however, p<q).

Next, the operation of the solid-state image pickup device 1 according to the embodiment will be explained.

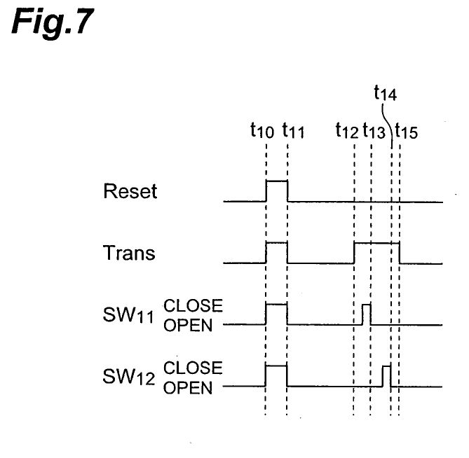

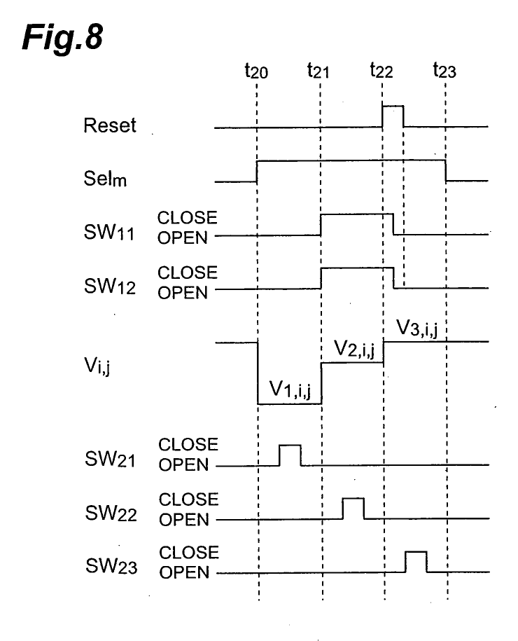

FIG. 7 and FIG. 8 are a timing chart for explaining the operation of the solid-state image pickup device 1 according to the embodiment. The operation to be explained below is performed based on various kinds of control signals outputted from a control part (not shown). The switch SW_{i,j} provided so as to correspond to each photosensitive part a_{i,j} is set so that the bias potential V_{bias} is inputted into the discharge transistor T₃.

The level change of the discharge control signal Reset inputted into the gate terminal of the discharge transistor T₃ (refer to FIG. 3) of the photosensitive part a_{i,j}, the level change of the transmission control signal Trans inputted into the gate terminal of the transmission transistor T₂ of the photosensitive part a_{i,j}, the opening/closing operation of the switch SW₁₁ of the photosensitive part a_{i,j}, and the opening/closing operation of the switch SW₁₂ of the photosensitive part a_{i,j} are shown in FIG. 7 beginning at the top. The operation shown in this figure is simultaneously performed in all the photosensitive parts a_{i,j} contained in all the sections A_{m,n} in the light detecting part 10.

At a time t₁₀, each of the discharge control signal Reset and transmission control signal Trans becomes a high level, and each of the switch SW₁₁ and switch SW₁₂ of the photosensitive part a_{i,j} is closed. Thereby, the charges of each of the photodiode PD, first capacitor part C₁₁ and second capacitor part C₁₂ are initialized.

At a time t₁₁, each of the discharge control signal Reset and transmission control signal Trans change to a low level, and each of switch SW₁₁ and switch SW₁₂ of the photosensitive part a_{i,j} is opened. In this state, when light enters into the photodiode PD, the charges corresponding to the amount of incident light occur in the photodiode, and are accumulated in the junction capacity part of the photodiode PD.

The transmission control signal Trans changes to a high level at a time t₁₂, and the transmission control signal Trans changes to a low level at a time t₁₅. After the switch SW₁₁ is once closed in the period from the time t₁₂ to the time t₁₅ when the transmission control signal Trans is at a high level, the switch SW₁₁ is opened at the time t₁₃ after the switch SW₁₁ is once closed, and the switch SW₁₂ is opened at a time t₁₄ after the switch SW₁₂ is once closed.

The charges generated in the photodiode PD from the time t₁₁ to the time t₁₃ are accumulated in the first capacitor part C₁₁ by performing the above operation in each photosensitive part a_{i,j}, and the charges generated in the photodiode PD from the time t₁₃ to the time t₁₄ are accumulated in the second capacitor part C₁₂.

However, when the capacity value of the first capacitor part C₁₁ is smaller than that of the junction capacity part of the photodiode PD and the stronger light enters (that is, when the first capacitor part C₁₁ is saturated), the charges which do not exceed the capacity of the first capacitor part C₁₁ out of the charges generated in the photodiode PD from the time t₁₁ to the time t₁₃ are accumulated in the first capacitor part C₁₁. In this case, the charges exceeding the capacity of the first capacitor part C₁₁ out of the charges generated in the photodiode PD from the time t₁₁ to the time t₁₃, and the charges generated in the photodiode PD from the time t₁₃ to the time t₁₄ are accumulated in the second capacitor part C₁₂.

FIG. 8 shows the level change of the discharge control signal Reset inputted into the gate terminal of the discharge transistor T₃ (refer to FIG. 3) of the photosensitive part a_{i,j}, the level change of the m-th line select control signal Selₘ inputted into the gate terminal of the selection transistor T₄ of the photosensitive part a_{i,j}, the opening/closing operation of the switch SW₁₁ of the photosensitive part a_{i,j}, the opening/closing operation of the switch SW₁₂ of the photosensitive part a_{i,j}, the level change of the voltage V_{i,j} outputted from the photosensitive part a_{i,j}, the opening/closing operation of the switch SW₂₁ of the partial holding circuit h_{i,j}, the opening/closing operation of the switch SW₂₂ of the partial holding circuit h_{i,j}, and the opening/closing operation of the switch SW₂₃ of the partial holding circuit h_{i,j} beginning at the top.

Each level change of the discharge control signal Reset and m-th line select control signal Selₘ out of the operation shown in this figure, and each opening/closing operation of the switch SW₁₁ and switch SW₁₂ are simultaneously performed in all the photosensitive parts a_{i,j} contained in the section A_{m,l}, to A_{m,N} of N pieces in the m-th line in the light detecting part 10, and is sequentially performed for the first line to the M-th line in the light detecting part 10.

The m-th line select control signal Selₘ becomes a high level for the period from the time t₂₀ after the above time t₁₅ to the time t₂₃. The discharge control signal Reset becomes a high level for a certain period of time from the time t₂₂ out of the period from the time t₂₂ to the time t₂₃. At the time t₂₀, each of the switch SW₁₁ and switch SW₁₂ is opened. Each of the switch SW₁₁ and switch SW₁₂ is closed at the subsequent time t₂₁, and after the time t₂₂ and before the discharge control signal Reset becomes a low level, each of the switch SW₁₁ and switch SW₁₂ is opened.

Since each of the switch SW₁₁ and switch SW₁₂ is opened in the period from the time t₂₀ to the time t₂₁, the first capacitor part C₁₁ is connected to the gate terminal of the amplification transistor T₁, and the second capacitor part C₁₂ is not connected. Therefore, the voltage V_{1,i,j} outputted to the line L_{n,i,j} through the selection transistor T₄ at this time corresponds to the amount of accumulated charges in the first capacitor part C₁₁. After the switch SW₂₁ of the partial holding circuit h_{i,j} is once closed in this period, the switch SW₂₁ is opened, and this voltage V_{1,i,j} is held in the capacitor C₂₁ of the partial holding circuit h_{i,j}.

Since each of the switch SW₁₁ and switch SW₁₂ is closed in the period from the time t₂₁ to the time t₂₂, both the first capacitor part C₁₁ and the second capacitor part C₁₂ are connected to the gate terminal of the amplification transistor T₁. Therefore, the voltage V_{2,i,j} outputted to the line L_{n,i,j} through the selection transistor T₄ at this time corresponds to the sum of the amount of accumulated charges in each of the first capacitor part C₁₁ and the second capacitor part C₁₂. After the switch SW₂₂ of the partial holding circuit h_{i,j} is once closed in this period, the switch SW₂₂ is opened, and this voltage V_{2,i,j} is held in the capacitor C₂₂ of the partial holding circuit h_{i,j}.

Since the discharge control signal Reset once becomes a high level in the period from the time t₂₂ to the time t₂₃, the voltage V_{3,i,j} outputted to the line L_{n,i,j} through the selection transistor T₄ at this time denotes a noise ingredient. Two kinds of a fixed pattern noise generated by the threshold variation of the transistor T₁ of each pixel and a random noise referred as a KTC noise generated at the time of the opening of the discharge transistor T₃ of each pixel are included in this noise ingredient. After the switch SW₂₃ of the partial holding circuit h_{i,j} is once closed in this period, the switch SW₂₃ is opened, this voltage V_{3,i,j} is held in the capacitor C₂₃ of the partial holding circuit h_{i,j}. Herein, as shown in FIG. 8, the SW₂₃ once closed is opened after a certain period of time after the discharge control signal becomes a low level.

When the switch SW₂₄ to SW₂₆ of the partial holding circuit h_{i,j} are closed sequentially for holding circuits H ₁ to H_{N} in the holding part 20 after the above time t₂₃, the voltage V_{1,i,j} to V_{3,i,j} are outputted to the lines L₁ to L₃ from the partial holding circuit h_{i,j}. Each of the added value Vₛᵤₘ (the above (1) formula) and average value Vₘₑₐₙ (the above (2) formula) is calculated as the differential signal between the voltage V_{1,i,j} at the times t₂₀ to t₂₁ and the voltage V_{3,i,j} at the times t₂₂ to t₂₃, and the differential signal between the voltage V_{2,i,j} at the times t₂₁ to t₂₂ and the voltage V_{3,i,j} at the times t₂₂ to t₂₃ for each of the sections A_{m,n} of M×N pieces in the light detecting part 10 by the calculating part 30 into which the voltages V_{1,i,j}, V_{2,i,j} and V_{3,i,j} are inputted.

Only the former fixed pattern noise can be removed out of the above two kinds of noises with this timing. When the latter random noise needs to also be removed, one signal-frame just before t₂₃ for all pixels is stored in an another place, and a difference between the voltage V_{1,i,j} at the times t₂₀ to t₂₁ and the voltage V_{2,i,j} at the times t₂₁ to t₂₂ from the signal just before t₂₃ before one frame is found. However, the reset operation at the times t₁₀ to t₁₁ is not required at this time.

The added value Vₛᵤₘ and average value Vₘₑₐₙ outputted from the calculating part 30 are inputted into the selecting part 60. When the absolute value of the added value Vₛᵤₘ is smaller than the first predetermined value Vₜₕ₁ (that is, when the amount of incident light to the section A_{m,n} is comparatively small and the first capacitor part C₁₁ is not saturated in the photosensitive part a_{i,j}), the added value Vₛᵤₘ is selected as the voltage Vₒᵤₜ outputted from the selecting part 60 in the selecting part 60. On the other hand, when the absolute value of the added value Vₛᵤₘ is larger than the first predetermined value Vₜₕ₁ (that is, when the amount of incident light to the section A_{m,n} is comparatively large and the first capacitor part C₁₁ is saturated in the photosensitive part a_{i,j}), the average value Vₘₑₐₙ is selected as the voltage Vₒᵤₜ outputted from the selecting part 60.

When the light detecting sensitivity is set to α in the case that the added value Vₛᵤₘ is outputted from the selecting part 60 at this time and the light detecting sensitivity is set to β in the case that the average value Vₘₑₐₙ is outputted from the selecting part 60, the ratio of α to β is represented by the following formula (4). In this embodiment, K is equal to 15. For example, this ratio can be set to 64:1 by appropriately setting the capacity value of each of the first capacitor part C₁₁ and second capacitor part C₁₂.

$$\begin{matrix}[ Formula 4 ] & \\ α \text{:} β = \frac{K}{{C}_{11}} \text{:} \frac{1}{{C}_{11} + {C}_{12}} = \frac{K ( {C}_{11} + {C}_{12} )}{{C}_{11}} \text{:} 1 & ( 4 )\end{matrix}$$

However, when the amount of incident light to a certain section A_{m,n} is still larger, both the first capacitor part C₁₁ and the second capacitor part C₁₂ may be saturated in the photosensitive part a_{i,j} contained in the section A_{m,n}. In such a case, the discharge control signal Reset and each transmission control signal Trans are respectively set to a high level in each photosensitive part a_{i,j} contained in the section A_{m,n}, and the charges generated in the photodiode PD are inputted into the integration circuit 40 via the switch SW_{i,j} and the line L₀.

The charges generated in all the photodiodes PD in the section A_{m,n} are accumulated in the capacitor C₄ of the integration circuit 40, and the voltage Vᵢₙₜ corresponding to the amount of accumulated charges in the capacitor C₄ is outputted from the integration circuit 40. The voltage outputted from the integration circuit 40 is inputted in the CDS circuit 50 during the charge accumulation period in the integration circuit 40, and the voltage V_{cds} corresponding to the difference in the voltages outputted from the integration circuit 40 at each of the initial time and finish time of the charge accumulation period is outputted.

Since the capacity value of the capacitor C₄ of the integration circuit 40 can be enlarged as compared with the first capacitor part C₁₁ and second capacitor part C₁₂ of each photosensitive part a_{i,j}, the capacitor C₄ can be hardly saturated even if the amount of incident light to the section A_{m,n} is still larger.

When the absolute value of the added value Vₛᵤₘ is larger than the first predetermined value Vₜₕ₁, and the absolute value of the average value Vₘₑₐₙ is smaller than the second predetermined value Vₜₕ₂ (that is, when the second capacitor part C₁₂ is not saturated although the amount of incident light to the section A_{m,n} is comparatively larger and the first capacitor part C₁₁ is saturated in the photosensitive part a_{i,j}), the average value Vₘₑₐₙ is selected as the voltage Vₒᵤₜ outputted from the selecting part 60.

In neither case (when the amount of incident light to the section A_{m,n} is still larger and the both the first capacitor part C₁₁ and the second capacitor part C₁₂ are saturated in the photosensitive part a_{i,j}), the voltage V_{cds} is selected as the voltage Vₒᵤₜ outputted from the selecting part 60. That is, the voltage Vₒᵤₜ outputted from the selecting part 60 is represented by the above formula (3).

The A/D conversion of the voltage Vₒᵤₜ outputted from the selecting part 60 is performed by the A/D converter circuit 70, and the digital value corresponding to the voltage Vₒᵤₜ is outputted from the A/D converter circuit 70. The digital value outputted from this A/D converter circuit 70 is shifted by only the required number of bits corresponding to any selected in the selecting part 60 by the bit shift circuit 80.

When the voltage Vₒᵤₜ outputted from the selecting part 60 is added value Vₛᵤₘ, the bit shift of the digital value outputted from the A/D converter circuit 70 is not performed in the bit shift circuit 80. When the voltage Vₒᵤₜ outputted from the selecting part 60 is the average value Vₘₑₐₙ, the digital value outputted from the A/D converter circuit 70 is shifted by only p bits to a higher order in the bit shift circuit 80. When the voltage Vₒᵤₜ outputted from the selecting part 60 is the voltage V_{cds}, the digital value outputted from the A/D converter circuit 70 is shifted by only q bits to a higher order in the bit shift circuit 80.

Herein, p and q are appropriately set according to the capacity value of the first capacitor part C₁₁ of each photosensitive part a_{i,j}, the sum of the capacity values of the first capacitor part C₁₁ and second capacitor part C₁₂ of each photosensitive part a_{i,j}, the number of photosensitive parts a_{i,j} contained in the section A_{m,n} and the capacity value of the capacitor C₄ of the integration circuit 40. The digital value outputted from the bit shift circuit 80 denotes the amount of incident light to each section A_{m,n} regardless of any input voltage selected in the selecting part 60.

As described above, the solid-state image pickup device 1 according to the embodiment can measure the amount of incident light to each section A_{m,n} with a high dynamic range, and can obtain an image excellent in contrast. Since the solid-state image pickup device 1 according to the embodiment does not amplify the signal charges outputted from the photodiode with the noise by the integration circuit when the amount of incident light is small, but outputs the charges generated in the photodiode PD in the photosensitive part a_{i,j} in each section A_{m,n} through the source follower circuit consisting of the amplification transistor T₁ and the selection transistor T₄, the solid-state image pickup device 1 can obtain an image excellent in the S/N ratio.

It is preferable that the capacity value of the capacity part for accumulating the charges in the integration circuit 40 can be set in multiple-stages. Thereby, the dynamic range of the optical detection can be further enlarged.

The present invention can be used for the photosensitive part and the solid-state image pickup device, and the solid-state image pickup device according to the present invention can obtain an image excellent in both contrast and an S/N ratio.

From the invention thus described, it will be obvious that the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A photosensitive part comprising:
a photodiode for generating charges corresponding to the intensity of incident light;
a first capacitor part and a second capacitor part for respectively accumulating the charges;
an amplification transistor having a gate terminal connected to at least one of the first capacitor part and the second capacitor part and outputting a voltage corresponding to the charges accumulated in at least one of the first capacitor part and the second capacitor part, connected to the gate terminal;
a transmission transistor for transferring the charges generated in the photodiode to the first capacitor part via a first switch and transferring the charges to the second capacitor part via a second switch;
a discharge transistor for initializing the charges of each of the first capacitor part and the second capacitor part; and
a selection transistor for alternatively outputting the voltage outputted from the amplification transistor.

2. A solid-state image pickup device comprising:
a light detecting part including sections A_{1,1} to A_{M,N} of M×N pieces one-dimensionally or two-dimensionally arranged and having the photosensitive parts of K pieces according to claim 1 arranged in a section A_{m,n} in the m-th line and n-th column;
a holding part for holding first voltages outputted through the selection transistor from the amplification transistor when the gate terminal of the amplification transistor of each of the photosensitive part of K pieces contained in the section A_{m,n} is connected to at least one of the first capacitor part and the second capacitor part, and holding second voltages outputted through the selection transistor from the amplification transistor when the gate terminal of the amplification transistor is connected to both the first capacitor part and the second capacitor part; and
a calculating part for calculating and outputting the added value of the first voltages outputted from each of the photosensitive parts of K pieces contained in the section A_{m,n} and held by the holding part, and calculating and outputting the average value of the second voltages outputted from each of the photosensitive part of K pieces contained in the section A_{m,n} and held by the holding part (M and N are an integer of 1 or more; at least one of M and N is an integer of 2 or more; K is an integer of 2 or more; m is an optional integer of 1 to M; and n is an optional integer of 1 to N).

3. The solid-state image pickup device according to claim 2, further comprising a selecting part for inputting the added value and average value outputted from the calculating part for each section A_{m,n}, outputting the added value when the absolute value of the added value is smaller than a predetermined value and outputting the average value when not so.

4. The solid-state image pickup device according to claim 2, further comprising:
a connection switching part having a first end provided for each of the photosensitive parts of K pieces contained in the section A_{m,n} and connected to the discharge transistor of the photosensitive part, and a second end for inputting bias potential for initializing the charges of each of the first capacitor part and second capacitor part of the photosensitive part, and a third end, and electrically connecting between the first end and the second end, or between the first end and the third end; and
an integration circuit having an input terminal connected to the third end of the connection switching part, accumulating the charges flowing-in through the first end and the third end of the connection switching part from the photosensitive parts of K pieces contained in the section A_{m,n} in a capacitor, and outputting the integration value corresponding to the amount of accumulated charges.

5. The solid-state image pickup device according to claim 4, further comprising a selecting part for inputting the added value and average value outputted from the calculating part for each section A_{m,n}, inputting the integration value outputted from the integration circuit, outputting the added value when the absolute value of the added value is smaller than a first predetermined value, outputting the average value when the absolute value of the added value is larger than the first predetermined value and the absolute value of the average value is smaller than a second predetermined value, and outputting the integration value in neither case.
